(19) United States
(12) Patent Application Publication
(10) Pub. No.: US 2006/0209914 A1
(43) Pub. Date: Sep. 21, 2006

(54) Semiconductor device and manufacturing method thereof

(75) Inventors: Kan Takada, Kawasaki (JP); Osamu Aoki, Kawasaki (JP); Tsuyoshi Yamamoto, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 11/257,125

(22) Filed: Oct. 25, 2005

(30) Foreign Application Priority Data
Mar. 16, 2005 (JP) 2005-075752

(51) Int. Cl. H01S 5/00; H01S 3/04

(52) U.S. Cl. 372/46.01; 372/43.01; 372/44.01

(57) ABSTRACT

In order to reduce the parasitic capacitance of the device and obtain an enhanced high-speed response characteristic while assuring the reliability of the device, a semiconductor device is provided such that it comprises: a mesa structure formed on a semiconductor substrate and including a first cladding layer, an active layer, a second cladding layer, a first protective layer and a second protective layer each covering respective side of the active layer, and a cap layer formed between the first protective layer and the second protective layer and covering the top surface of the active layer, wherein aluminum is included only in the active layer; and a buried layer for burying the mesa structure, wherein the first cladding layer, the first protective layer, the second protective layer, and the second cladding layer constitute the side of the mesa structure.

### CROSS REFERENCE TO RELATED APPLICATIONS

This application is based on and hereby claims priority to Japanese Application No. 2005-075752 filed on Mar. 16, 2005 in Japan, the contents of which are hereby incorporated by reference.

### BACKGROUND OF THE INVENTION

(1) Field of the Invention

The present invention relates to a semiconductor device and manufacturing method thereof, which is suitable for use with a semiconductor device comprising an active layer composed of semiconductor materials including aluminum Al, such as InAlGaAs material systems, for example.

(2) Description of Related Art

In recent years, request for further cost reduction, miniaturization, and power consumption reduction of optical modules has been rising.

Under such circumstances, development has been propelled for direct modulation semiconductor lasers of a communication wavelength band in which they are operable without a Peltier element.

Particularly, it is effective to compose a quantum well active layer using InAlGaAs material systems, in order to realize a sufficient high-speed modulation operation at high temperatures. In other words, since composing the quantum well active layer using an InAIGaAs related semiconductor material can increase the depth of the conduction band in the quantum well structure (amount of band offset ΔEc of the conduction band), overflow of the carrier at high temperatures can be suppressed, whereby sufficiently high-speed modulation operation at high temperatures can be realized.

Generally, in semiconductor lasers, a ridge waveguide structure, a buried heterostructure, or the like are employed in order to confine light waves within an active layer constituting a waveguide structure and to inject carriers effectively.

Among these, the buried heterostructure is an advantageous structure to realize low-threshold and high-speed modulation operation due to its ability to suppress, in comparison with other structures, diffusion of electric current to outside of the active layer.

As the buried heterostructures, there are, for example, a pnpn buried heterostructure, a semi-insulating buried heterostructure (SI-BH structure), or the like. Particularly, the semi-insulating buried heterostructure is advantageous in that it can reduce the parasitic capacitance of the device, in comparison with the pnpn buried heterostructure.

Here, as a manufacturing method of the semiconductor laser comprising a buried heterostructure, there is the first method (hereafter referred to as the first manufacturing method) comprising the steps of, firstly forming a mesa structure including an active layer by etching, and burying the mesa structure with the buried layer which can constitute a buried heterostructure.

In addition, there is also proposed a manufacturing method wherein an active layer including Al is prevented from being exposed to the atmosphere during the manufacturing process, by forming the mesa structure not by etching, but by stacking via selective growth, and further covering the peripheral side surface of the active layer including Al with a protective film (for example, see Japanese Patent Laid-open (Kokai) 2003-133647, hereafter referred to as the second manufacturing method).

### SUMMARY OF THE INVENTION

Now, when the mesa structure is formed on the substrate by selective growth, as with the above-mentioned second manufacturing method, the mesa structure has a slope with an angle of about 55 degrees to the substrate since the mesa structure grows to have two (111) B faces. Thus it is difficult to increase the height of mesa structure, whereby it is difficult to reduce the parasitic capacitance of the device although oxidation of the active layer including Al can be suppressed.

On the other hand, it is effective to increase the height of the mesa structure and adopt an SI-BH structure in which the mesa structure is buried in a semi-insulating semiconductor layer in order to reduce the parasitic capacitance of the device and achieve a good high-speed response characteristic. It is effective to form the mesa structure by etching, as with the above-mentioned first manufacturing method in order to increase the height of the mesa structure and adopt the SI-BH structure.

In the above-mentioned first manufacturing method, however, it is necessary to take out the semiconductor wafer from the growth chamber into the atmosphere to perform mesa etching, for example. Thus, when manufacturing a semiconductor laser having an active layer composed of a semiconductor material including Al which may be easily oxidized such as an InAlGaAs related (group) material, the active layer composed of a semiconductor material including Al is exposed to the atmosphere and oxidized. If an oxide film is formed on the active layer, it may cause defects, which may lead to increase of leakage current, resulting in decrease of light output and reliability degradation of the device.

In addition, although a process is added to remove the oxide film formed in the active layer region of the mesa structure as a pre-process of the burying process, for example, it is still difficult to completely remove the effect of oxidation. For example, when performing a pre-process to remove the oxide film by wet-etching, setting the etching condition is difficult and, furthermore, the interface shape of the mesa structure may be changed by the etching.

It is an object of the present invention, which has been made in view of the above-mentioned problems, to provide a semiconductor device and a manufacturing method thereof which can reduce the parasitic capacitance of the device to achieve a better high-speed response characteristic while assuring the reliability of the device.

Therefore, in accordance with one aspect of the present invention, a semiconductor device comprises: a mesa structure formed on a semiconductor substrate and including a first cladding layer, an active layer, a second cladding layer, a first protective layer and a second protective layer each covering respective side faces of the active layer, and a cap layer formed between the first protective layer and the second protective layer and covering the top face of the active layer, wherein aluminum is included only in the active layer; and a buried layer for burying the mesa structure, wherein the first cladding layer, the first protective layer, the second protective layer, and the second cladding layer constitute the side of the mesa structure.

In accordance with another aspect of the present invention, a manufacturing method of the semiconductor device comprises: forming, on a semiconductor substrate, a first cladding layer composed of an aluminum-free semiconductor material and a protective layer composed of an aluminum-free semiconductor material; forming a groove in the protective layer; forming, within the groove, an active layer composed of a semiconductor material including aluminum; forming a cap layer composed of an aluminum-free semiconductor material such that the cap layer covers the top face of the active layer; forming, over the protective layer and the cap layer, a second cladding layer composed of an aluminum-free semiconductor material; forming a mesa structure including the first cladding layer, the active layer, the cap layer, the protective layer, and the second cladding layer such that the mesa structure has a width wider than the width of the active layer.

Thus, according to the semiconductor device of the present invention and the manufacturing method thereof, it is advantageous in that the parasitic capacitance of the device is reduced and an enhanced high-speed response characteristic is obtained, while assuring the reliability of the device.

### BRIEF DESCRIPTION OF THE DRAWINGS

FIG. 1 is a schematic sectional view showing the arrangement of a semiconductor device according to a first embodiment of the present invention.

FIGS. 2(a) to 2(f) are schematic sectional views illustrating a manufacturing method of the semiconductor device according to the first embodiment of the present invention.

FIG. 3 is a schematic sectional view showing the arrangement of a semiconductor device according to a second embodiment of the present invention.

FIG. 4 is a schematic sectional view showing the arrangement of a semiconductor device according to a third embodiment of the present invention.

### DESCRIPTION OF THE PREFERRED EMBODIMENTS

A semiconductor device and a manufacturing method thereof according to embodiments of the present invention will be described below with reference to drawings.

[First Embodiment]

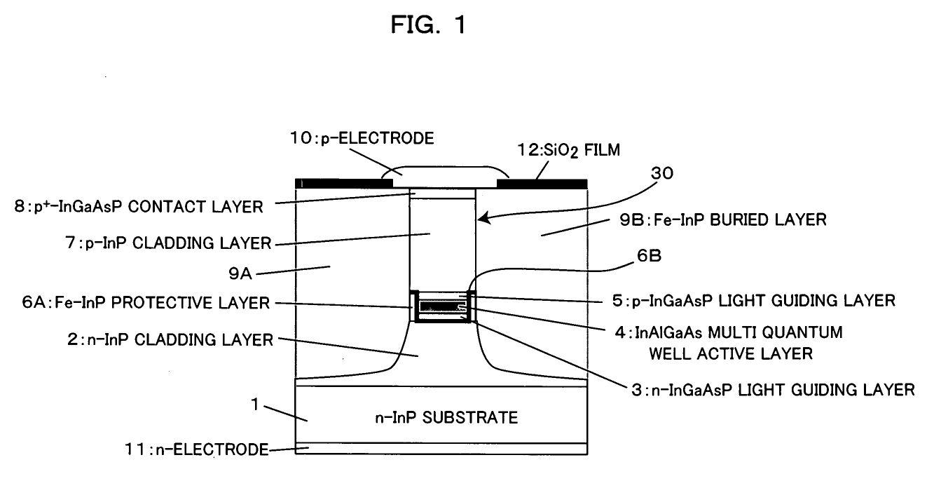

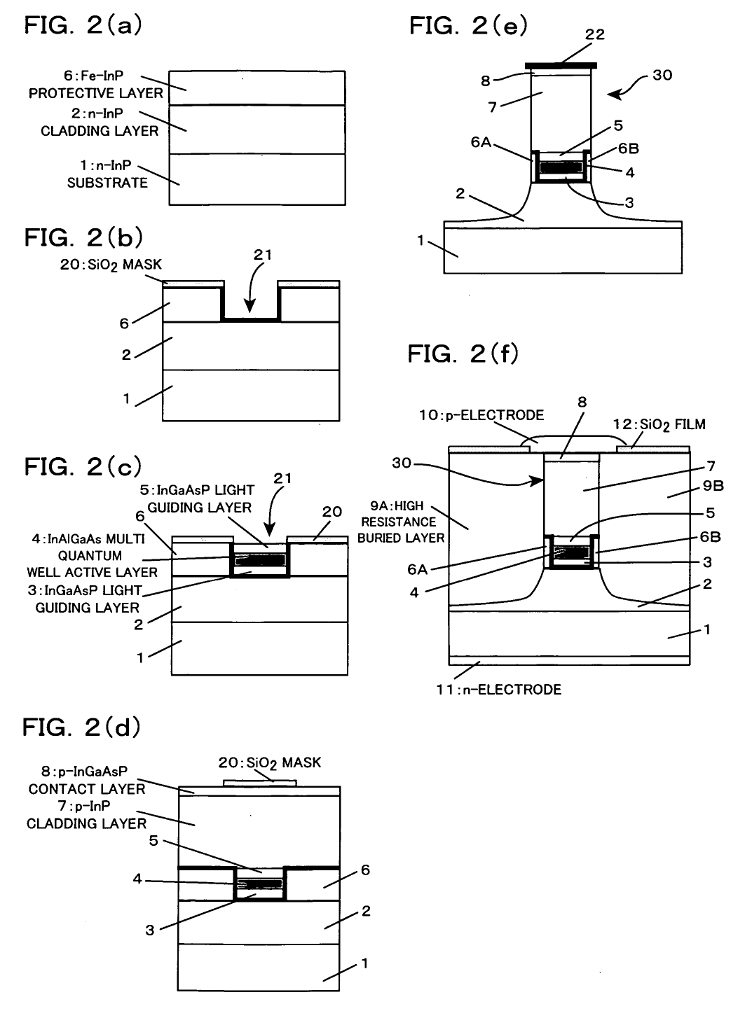

First, a semiconductor device and a manufacturing method thereof according to the first embodiment of the present invention will be described with reference to FIGS. 1 and 2(a) to 2(f).

The semiconductor device according to the present embodiment is, for example, a semiconductor laser (such as a semiconductor laser with a 1.3 μm wavelength band; semiconductor light emitting device) comprising an active layer composed of a semiconductor material including aluminum Al, and employing a semi-insulating buried heterostructure (SI-BH structure; Semi-Insulating Buried Heterostructure) as the current blocking structure.

In other words, the semiconductor laser comprises, as shown in FIG. 1, an n-type InP cladding layer (first cladding layer, lower cladding layer) 2, an n-type InGaAsP light guiding layer (first light guiding layer, lower light guiding layer) 3, an InAlGaAs multi quantum well active layer (waveguide core layer, current injection layer) 4 with a multi quantum well structure composed of InAlGaAs material systems, a p-type InGaAsP light guiding layer (second light guiding layer, upper light guiding layer) 5, Fe-doped Fe—InP protective layers (semi-insulating semiconductor layer, high resistance semiconductor layer, first protective layer, second protective layer) 6A and 6B covering respective sides of the InAlGaAs multi quantum well active layer 4, a p-type InP cladding layer (second cladding layer, upper cladding layer) 7, a p-type InGaAsP contact layer (p⁺ InGaAsP layer) 8, Fe-doped Fe—InP buried layers (semi-insulating current blocking layer, high resistance semiconductor layer, first buried layer, second buried layer) 9A and 9B, a p-electrode 10, an n-electrode 11, and an SiO₂ film (insulating film) 12, on an n-type InP substrate (n-InP substrate, semiconductor substrate) 1.

Here, the first protective layer 6A and the second protective layer 6B are configured as Fe—InP layers to have the same material and composition as with the first buried layer 9A and the second buried layer 9B. Therefore, both the first protective layer 6A and the second protective layer 6B function as the semi-insulating current blocking layer.

Particularly, in the present embodiment, the first protective layer 6A and the second protective layer 6B are rendered to have a smaller refractive index than the active layer 4 in order to enhance the optical confinement in the transverse direction of the active layer 4 and improve the emission efficiency.

In addition, the lower light guiding layer 3, the active layer 4, and the upper light guiding layer 5 are all formed between the first protective layer 6A and the second protective layer 6B as shown in FIG. 1. In other words, the first protective layer 6A is provided between the first buried layer 9A and a combination of the lower light guiding layer 3, the active layer 4 and the upper light guiding layer 5, whereas the second protective layer 6B is provided between the second buried layer 9B and a combination of the lower light guiding layer 3, the active layer 4 and the upper light guiding layer 5.

This means that the width of the active layer 4 has made narrower than the width of the mesa structure 30 (i.e., width of the upper cladding layer 7 and the lower cladding layer 2).

In addition, the upper light guiding layer 5 is formed, as shown in FIG. 1, by an aluminum-free semiconductor material to cover the top surface of the active layer 4, and also functions as a cap layer such that the surface of the active layer 4 is prevented from being exposed to the atmosphere and oxidized during the manufacturing process, as discussed below. Therefore, the upper light guiding layer 5 is also referred to as the cap layer.

On the other hand, the lower light guiding layer 3 functions as a buffer layer when forming the active layer 4 above the lower cladding layer 2. Therefore the lower light guiding layer 3 is also referred to as the buffer layer.

Here, in the present embodiment, although the light guiding layers 3 and 5 are provided, it may be configured such that no light guiding layer is provided. However, it is necessary to provide a cap layer (protective layer) composed of an aluminum-free semiconductor material instead of the light guiding layer 5 provided at the upper side of the active layer 4, so that the face of the active layer 4 is prevented from being exposed to the atmosphere and oxidized during the manufacturing process. In this case, the cap layer may be a p-type InGaAsP layer, same as the above-mentioned upper light guiding layer 5, or may be a p-type InP layer, same as the upper cladding layer 7.

In the present embodiment, the mesa structure 30 comprises a lower cladding layer 2, a lower light guiding layer 3, an active layer 4, an upper light guiding layer 5 as a cap layer, a first and a second protective layers 6A and 6B, an upper cladding layer 7, and a contact layer 8. Here the mesa structure 30 may be configured such that it does not comprise the contact layer 8.

Particularly, in the present embodiment, aluminum Al is included only in the active layer 4. In other words, the lower cladding layer 2, the lower light guiding layer 3, the upper light guiding layer 5, the first and the second protective layers 6A and 6B, the upper cladding layer 7, and the contact layer 8 are formed using an aluminum-free semiconductor material.

Since the mesa structure 30 thus configured is formed by etching such that, as described below, the width of the mesa structure 30 (i.e., width of the cladding layer immediately over the active layer 4) is wider than the width of the active layer 4, the side faces of the mesa structure 30 consist of the lower cladding layer 2, the first and the second protective layers 6A and 6B, the upper cladding layer 7. Therefore, the side face of the active layer 4 can be prevented from being exposed to the atmosphere and oxidized during the manufacturing process.

In addition, since the mesa structure 30 is formed not by the selective growth but by the etching, the height can be increased to about 3 μm. Thus it is expected that the parasitic capacitance of the device can be reduced. Then a semi-insulating buried heterostructure (SI-BH structure) is formed by burying the mesa structure 30 thus configured by the first and the second buried layers 9A and 9B which are the semi-insulating semiconductor layers.

Next, a manufacturing method of a semiconductor laser as the semiconductor device according to the present embodiment will be described, with reference to FIGS. 2(a) to 2(f). Here, crystal growth is performed by Metal Organic Chemical Vapor Deposition (MOCVD) or Molecular Beam Epitaxy (MBE), for example.

First, as shown in FIG. 2(a), an n-InP cladding layer (first cladding layer, lower cladding layer) 2, and an Fe-doped Fe—InP layer (protective layer) 6 are sequentially grown on the n-InP substrate 1. In other words, the lower cladding layer 2 and the protective layer 6 are formed using an aluminum-free semiconductor material.

Next, as shown in FIG. 2(b), after a dielectric mask (SiO₂ mask, for example) 20 having an opening with a width corresponding to the desired width of the active layer has been formed by a normal photolithography on the protective layer 6, a groove 21 to form the active layer 4 is formed by performing a selective etching (for example, wet etching; first etching) down to the upper surface of the lower cladding layer 2.

Here, the width of the groove 21 may be set such that no higher mode will arise in the horizontal transverse mode. The width of the groove 21 may be, for example, about 1.3 μm. In addition, the depth of the groove 21 may be about 0.2-0.3 μm, when the active layer 4 has a multi quantum well structure.

Then, as shown in FIG. 2(c), an n-InGaAsP layer (first light guiding layer, lower light guiding layer, buffer layer) 3, an InAlGaAs multi quantum well active layer of the multi quantum well structure composed of InAlGaAs material systems (InAlGaAs related active layer; active layer composed of a semiconductor material including aluminum Al) 4, a p-InGaAsP layer (second light guiding layer, upper light guiding layer) 5 are selectively grown (selective growth) in sequence in the groove 21. In other words, an upper light guiding layer 5 composed of an aluminum-free semiconductor material is formed on an active layer 4 including aluminum Al. Subsequently, wafer is taken out from the growth chamber, and the SiO₂ mask 20 used as the selective growth mask is removed by wet etching, for example.

Here, the InAlGaAs multi quantum well active layer 4 may be formed as a structure in which, for example, an InAlGaAs well layer having a compressive strain of 1.5% and a thickness of 6 nm, and an InAlGaAs barrier layer having a tensile strain of 0.3% and a thickness of 10 nm are alternately stacked ten times.

Thus, the depth of the conduction band (amount of band offset ΔEc of the conduction band) in the quantum well structure can be increased to about 0.31 eV, since the active layer 4 is formed as a multi quantum well structure composed of InAlGaAs material systems. Therefore, overflow of electrons can be suppressed also at high temperatures, thereby preventing decrease in emission efficiency. As a result, a semiconductor laser having a good temperature characteristic and a wide modulation bandwidth can be realized.

Here, since the upper light guiding layer 5 which is formed to cover the top face of the active layer 4 using an aluminum-free semiconductor material functions as the cap layer, it can prevent the top face of the active layer 4 from being exposed to the atmosphere and oxidized when the wafer is taken out from the growth chamber.

Although the light guiding layers 3 and 5 are formed, the light guiding layers may not be formed. However, a cap layer (protective layer) composed of an aluminum-free semiconductor material must be provided in place of the light guiding layer 5 provided at the upper side of the active layer 4, in order to prevent the face of the active layer 4 from being exposed to the atmosphere and oxidized during the manufacturing process. In this case, the cap layer may be a p-type InGaAsP layer, same as the upper light guiding layer 5, or a p-type InP layer, same as the upper cladding layer 7.

Next, as shown in FIG. 2(d), a p-InP cladding layer (second cladding layer, upper cladding layer) 7 and a p-InGaAsP contact layer 8 are sequentially grown all over the protective layer 6 and the upper light guiding layer 5 serving as the cap layer. In other words, the upper cladding layer 7 and the contact layer 8 are formed using an aluminum-free semiconductor material. Subsequently, a dielectric mask (SiO₂ mask, for example) 22 having a desired width (wider than the width of the active layer 4) is formed as a mesa stripe forming mask for forming the mesa structure (mesa stripe) 30.

Subsequently, as shown in FIG. 2(e), etching is performed such that the width of the mesa structure 30 becomes wider than the width of the active layer 4 [for example, dry etching such as ICP-RIE (Inductively Coupled Plasma Reactive Ion Etching), (inductive coupling type plasma reactive ion etching: second etching).

Thus the first and the second protective layers 6A and 6B are formed on both side faces of the active layer 4. Here, it is preferable that the first and the second protective layers 6A and 6B are as thin as possible and thick enough to prevent the Al included in the active layer 4 from being oxidized.

In addition, the height of the mesa structure 30 formed by etching can be increased to about 3 μm. Thus, the parasitic capacitance of the device can be reduced.

Here, the mesa structure 30 may be formed as a structure including a lower cladding layer 2, an active layer 4, an upper light guiding layer 5 as the cap layer, a first and a second protective layers 6A and 6B, an upper cladding layer 7, and a contact layer 8. Alternatively, the mesa structure 30 may be formed as a structure not including the contact layer 8.

The mesa structure 30 includes aluminum Al only in the active layer 4. In other words, the lower cladding layer 2, the lower light guiding layer 3, the upper light guiding layer 5, the first and the second protective layers 6A and 6B, the upper cladding layer 7, and the contact layer 8 are formed using an aluminum-free semiconductor material. Here, the lower light guiding layer 3 may be formed using an aluminum-free semiconductor material.

Particularly, a mesa structure 30 having a width which is wider than the width of the active layer 4 is formed. In the side face of the mesa structure 30 thus formed, the lower cladding layer 2, the first and the second protective layers 6A and 6B, and the upper cladding layer 7 are exposed. In other words, the side face of the active layer 4 is covered by the first and the second protective layers 6A and 6B such that it will not be exposed. Therefore, the side face of the active layer 4 is prevented from being exposed to the atmosphere and oxidized during the etching process to form the mesa structure 30.

Subsequently, as shown in FIG. 2(f), an Fe—InP buried layers (the semi-insulating current blocking layer, the first buried layer and the second buried layer) 9A and 9B are grown (burying regrowth) so that the mesa structure 30 formed as described above is buried. Thus a semi-insulating buried heterostructure (SI-BH structure) as a current blocking structure is formed.

Then, after the Sio₂ mask 22 has been removed, an SiO₂ film (insulating film) 12 is formed over the entire face. Then, the SiO₂ film 12 over the contact layer 8 is removed, and a p-electrode 10 is formed. On the other hand, an n-electrode 11 is formed on the backside of the n-InP substrate 1.

Therefore, according to the semiconductor device (semiconductor laser) and the manufacturing method of the present embodiment, the active layer 4 including Al can remain intact from the effect of oxidation (such as formation of an oxide film) since the active layer 4 including Al can be prevented from being exposed to the atmosphere during the manufacturing process. Thus, it is advantageous in that generation of defect can be prevented in a semiconductor laser comprising the active layer 4 including Al, and increase of leakage current and the resulting decrease of light output can be suppressed (degradation of laser characteristics can be prevented), thereby assuring the reliability of the device. In addition, yield rate can also be enhanced.

In addition, it is advantageous in that the height of the mesa structure 30 can be increased by forming the mesa structure 30 via etching, and the parasitic capacitance of the device can be reduced by employing the SI-BH structure, resulting in an enhanced high-speed response characteristic.

In addition, it is also advantageous that the process of removing the oxide film formed in the active layer region of the mesa structure 30 need not be performed as a pre-process of the burying process, since the active layer 4 including Al is prevented from being exposed to the atmosphere and oxidized during the manufacturing process.

[Second Embodiment]

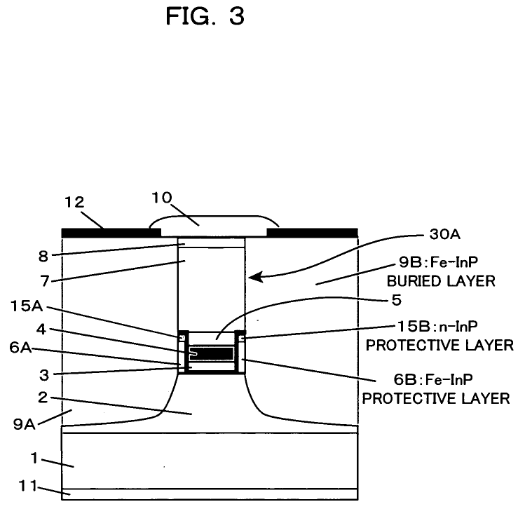

Next, a semiconductor device and the manufacturing method according to a second embodiment of the present invention will be described, with reference to FIG. 3.

The semiconductor device (semiconductor laser) according to the present embodiment differs from the above-mentioned first embodiment in the arrangement of the protective layers provided to sandwich the active layer 4 (and the light guiding layers 3 and 5) on the opposite sides. In other words, as shown in FIG. 3, with this semiconductor laser, a part of the protective layers provided to sandwich the active layer 4 (and the light guiding layers 3 and 5) on the opposite sides are n-InP protective layers 15A and 15B. Here, elements in FIG. 3 which are identical with those in FIG. 1 are given the same reference numerals.

Specifically, the semiconductor laser comprises, as shown in FIG. 3, Fe-doped Fe—InP protective layers (semi-insulating semiconductor layer, high resistance semiconductor layer, first protective layer, second protective layer) 6A and 6B covering respective sides of the InAlGaAs multi quantum well active layer (waveguide core layer, current injection layer) 4, and n-type InP protective layers (first protective layer, second protective layer) 15A and 15B. In other words, the first protective layer and the second protective layer protecting respective sides of the InAlGaAs multi quantum well active layer 4 have portions 6A and 6B composed of one material, and portions 15A and 15B composed of other materials. However, this is by no means limiting, and the first protective layer and the second protective layer may be configured so as to have portions of one composition and portions of other compositions.

In the present embodiment, aluminum Al is included only in the active layer 4, and the lower cladding layer 2, the lower light guiding layer 3, the upper light guiding layer 5, the first and the second protective layers 6A, 6B, 15A and 15B, the upper cladding layer 7, and the contact layer 8 are formed using an aluminum-free semiconductor material. In addition, the mesa structure 30A may be formed as a structure not including the contact layer 8.

Here, description of the details of the arrangement, which are identical with those of the above-mentioned first embodiment, is omitted.

Next, a manufacturing method of the semiconductor laser according to the present embodiment will be described.

With the present embodiment, at the process of sequentially growing, on the n-InP substrate 1, the n-InP cladding layer (the first cladding layer, the lower cladding layer) 2 and the Fe—InP layer (protective layer; layer consisting of one material or composition) 6 [see FIG. 2(a)], in the manufacturing process of the above-mentioned first embodiment, an n-InP layer (layer consisting of other materials or composition, which turns into an n-InP protective layers 15A and 15B by mesa etching) may be further grown on the protective layer 6. Thus, protective layers 15A and 15B composed of an aluminum-free semiconductor material are formed on the protective layers 6A and 6B, resulting in a protective layer having a two-layer structure.

Here, description of the other processes, being identical with those of the above-mentioned first embodiment, is omitted.

Therefore, according to the semiconductor device (semiconductor laser) and the manufacturing method of the present embodiment, the active layer 4 including Al can remain intact from the effect of oxidation (such as formation of an oxide film) since the active layer 4 including Al may be prevented from being exposed to the atmosphere during the manufacturing process. Thus, it is advantageous in that generation of defect can be prevented in a semiconductor laser comprising the active layer 4 including Al, and increase of leakage current and the resulting decrease of light output can be suppressed (degradation of laser characteristics can be prevented), thereby assuring the reliability of the device. In addition, yield rate can also be enhanced.

In addition, it is advantageous in that the height of the mesa structure 30A can be increased by forming the mesa structure 30A via etching, and the parasitic capacitance of the device can be reduced by employing the SI-BH structure, resulting in an enhanced high-speed response characteristic.

In addition, it is also advantageous that the process of removing the oxide film formed in the active layer region of the mesa structure 30A need not be performed as a pre-process of the burying process, since the active layer 4 including Al is prevented from being exposed to the atmosphere and oxidized during the manufacturing process.

[Third Embodiment]

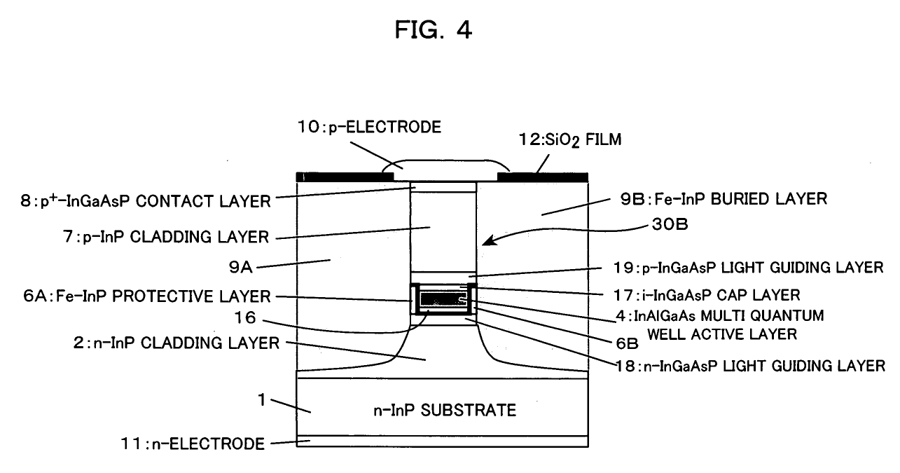

Next, a semiconductor device and the manufacturing method according to a third embodiment of the present invention will be described, with reference to FIG. 4.

The semiconductor device (semiconductor laser) according to the present embodiment differs from the above-mentioned first embodiment in the arrangement of the light guiding layer. In other words, while a lower light guiding layer (n-InGaAsP light guiding layer 3) having a functionality of the buffer layer, and an upper light guiding layer (p-InGaAsP light guiding layer 5) having a functionality of the cap layer are used in the above-mentioned first embodiment, the present embodiment differs in that layers having respective functionalities are separately provided.

Specifically, the semiconductor laser comprises, as shown in FIG. 4, an undoped i-InGaAsP buffer layer 16, an InAlGaAs multi quantum well active layer (a waveguide core layer, a current injection layer) 4, and an undoped InGaAsP cap layer 17 are provided between the first protective layer (Fe—InP protective layer, semi-insulating semiconductor layer, high resistance semiconductor layer) 6A and the second protective layer (Fe—InP protective layer, semi-insulating semiconductor layer, high resistance semiconductor layer) 6B, an n-InGaAsP light guiding layer (first light guiding layer, lower light guiding layer) 18 is further provided at the lower side of the first Fe—InP protective layer 6A and the i-InGaAsP buffer layer 16 (i.e., at the lower side of the active layer 4), and a p-InGaAsP light guiding layer (second light guiding layer, upper light guiding layer) 19 is provided at the upper side of the second Fe—InP protective layer 6B and the i-InGaAsP cap layer 17 (i.e., at the upper side of the active layer 4). Here, elements in FIG. 4 which are identical with those in FIG. 1 are given the same reference numerals.

In other words, the present embodiment employs a structure in which the circumference of the active layer 4 is covered by the buffer layer 16, the cap layer 17, and the protective layers 6A and 6B, with the buffer layer 16 and the cap layer sandwiching the active layer 4 from the top and the bottom, the protective layers 6A and 6B sandwiching the active layer 4 from the right and the left, and the top and the bottom of the sandwiched structure are furthermore sandwiched by the light guiding layers 18 and 19.

In the present embodiment, as shown in FIG. 4, the first protective layer 6A is provided between the first buried layer 9A and a combination of the buffer layer 16, the active layer 4 and the cap layer 17, whereas the second protective layer 6B is provided between the second buried layer 9B and a combination of the buffer layer 16, the active layer 4 and the cap layer 17.

In addition, the cap layer 17 is formed, as shown in FIG. 4, using an aluminum-free semiconductor material to cover the top face of the active layer 4 such that the face of the active layer 4 is prevented from being exposed to the atmosphere and oxidized during the manufacturing process.

In the present embodiment, the mesa structure 30B is formed as a structure including a lower cladding layer 2, a lower light guiding layer 18, a buffer layer 16, an active layer 4, a cap layer 17, an upper light guiding layer 19, a first and a second protective layers 6A and 6B, an upper cladding layer 7, and a contact layer 8. Alternatively, the mesa structure 30 may be formed as a structure not including the contact layer 8.

Particularly, in the present embodiment, aluminum Al is included only in the active layer 4. In other words, the lower cladding layer 2, the lower light guiding layer 18, the buffer layer 16, the cap layer 17, the upper light guiding layer 19, the first and the second protective layers 6A and 6B, the upper cladding layer 7, and the contact layer 8 are formed using an aluminum-free semiconductor material.

Since the mesa structure 30B thus configured is formed by etching so that, as described below, the width of the mesa structure 30B (i.e., width of the cladding layer immediately over the active layer 4) is wider than the width of the active layer 4, the side face of the mesa structure 30B consists of the lower cladding layer 2, the lower light guiding layer 18, the first and the second protective layers 6A and 6B, the upper light guiding layer 19, the upper cladding layer 7. Therefore, the side face of the active layer 4 can be prevented from being exposed to the atmosphere and oxidized during the manufacturing process.

Note that in the present embodiment, both the lower light guiding layer 18 and the upper light guiding layer 19 are wider than the width of the active layer 4, as shown in FIG. 4. In addition, it is configured such that the band-gap energy of the light guiding layers 18 and 19 is lower than the band-gap energy of the first and the second protective layers 6A and 6B. Thus, the current injection efficiency to the active layer 4 can be enhanced.

Now, although the light guiding layers are provided at the upper side and the lower side of the active layer 4 respectively, this is by no means limiting and it may suffice to provide, for example, at least at the lower side (n side).

Here, description of the details of the arrangement, which are identical with those of the above-mentioned first embodiment, is omitted.

Next, a manufacturing method of the semiconductor laser according to the present embodiment will be described.

With the present embodiment, at the process of sequentially growing, on the n-InP substrate 1, the n-InP cladding layer (first cladding layer, lower cladding layer) 2 and the Fe—InP layer (protective layer; layer consisting of one material or composition) 6 [see FIG. 2(a)], in the manufacturing process of the above-mentioned first embodiment, an n-InGaAsP light guiding layer (first light guiding layer, lower light guiding layer) 18 is grown and formed after the lower cladding layer 2 has been formed and before the protective layer 6 is formed. In other words, the lower light guiding layer 18 is formed after the lower cladding layer 2 has been formed and before the protective layer 6 is formed. Here, the lower cladding layer 2, the lower light guiding layer 18, and the protective layer 6 are formed using an aluminum-free semiconductor material.

Additionally, at the process of forming a groove 21 [see FIG. 2(b)], selective etching (for example, wet etching: the first etching) is performed down to the upper surface of the lower light guiding layer 18 to form the groove 21, in the manufacturing process of the above-mentioned first embodiment.

Furthermore, at the process of sequentially growing, in the groove 21, the lower light guiding layer 3 as the buffer layer, the active layer 4, the upper light guiding layer 5 as the cap layer [see FIG. 2(c)], in the manufacturing process of the above-mentioned first embodiment, an i-InGaAsP buffer layer 16, an InAlGaAs multi quantum well active layer of a multi quantum well structure composed of InAlGaAs material systems (InAIGaAs related active layer, active layer composed of a semiconductor material including aluminum Al) 4, an i-InGaAsP cap layer 17 are sequentially and selectively grown (selective growth) in the groove 21. In other words, the cap layer 17 composed of an aluminum-free semiconductor material is formed on the active layer 4 including aluminum Al.

Here, since the cap layer 17 is formed to cover the top face of the active layer 4 using an aluminum-free semiconductor material, it can prevent the top face of the active layer 4 from being exposed to the atmosphere and oxidized when the wafer is taken out from the growth chamber.

Additionally, at the process of sequentially growing the upper cladding layer 7 and the contact layer 8 [see FIG. 2(d)] in the manufacturing process of the above-mentioned first embodiment, a p-InGaAsP light guiding layer (second light guiding layer, upper light guiding layer) 19, a p-InP cladding layer (second cladding layer, upper cladding layer) 7, a p-InGaAsP contact layer 8 are sequentially grown all over the Fe—InP layer (protective layer) 6 and the i-InGaAsP cap layer 17. In other words, the upper light guiding layer 19 is formed after the cap layer 17 has been formed and before the upper cladding layer 7 is formed. Here, the upper light guiding layer 19, the upper cladding layer 7, and the contact layer 8 are formed using an aluminum-free semiconductor material.

Subsequently, as with the above-mentioned first embodiment [see FIG. 2(e)], etching is performed (for example, dry etching such as ICP-RIE: second etching) such that the width of the mesa structure 30B becomes wider than the width of the active layer 4. The height of the mesa structure 30B thus formed by etching can be made higher than or equal to a predetermined height (about 3 μm, for example), whereby the parasitic capacitance of the device can be reduced.

Here, the mesa structure 30B is formed as a structure including a lower cladding layer 2, a lower light guiding layer 18, a buffer layer 16, an active layer 4, a cap layer 17, an upper light guiding layer 19, a first and a second protective layers 6A and 6B, an upper cladding layer 7, and a contact layer 8. Alternatively, the mesa structure 30B may be formed as a structure not including the contact layer 8.

The mesa structure 30B has aluminum Al included only in the active layer 4. In other words, the lower cladding layer 2, the lower light guiding layer 18, the buffer layer 16, the cap layer 17, the upper light guiding layer 19, the first and the second protective layers 6A and 6B, the upper cladding layer 7, and the contact layer 8 are formed using an aluminum-free semiconductor material.

Particularly, the mesa structure 30B having a width which is wider than the width of the active layer 4 is formed. The lower cladding layer 2, the lower light guiding layer 18, the first and the second protective layers 6A and 6B, the upper light guiding layer 19, and the upper cladding layer 7 are exposed on the side face of the mesa structure 30B thus formed. In other words, the side face of the active layer 4 is covered by the first and the second protective layers 6A and 6B so as not to be exposed. Therefore, the side face of the active layer 4 can be prevented from being exposed to the atmosphere and oxidized during the manufacturing process of forming the mesa structure 30B.

Subsequently, as with the above-mentioned first embodiment [see FIG. 2(f)], Fe—InP buried layers (semi-insulating current blocking layer, first buried layer, second buried layer) 9A and 9B are grown such that the mesa structure 30B thus formed is buried (burying regrowth), whereby a semi-insulating buried heterostructure (SI-BH structure) as a current blocking structure is formed.

Here, description of the other processes, being identical with those of the above-mentioned first embodiment, is omitted.

Therefore, according to the semiconductor device (semiconductor laser) and the manufacturing method of the present embodiment, the active layer 4 including Al can remain intact from the effect of oxidation (such as formation of an oxide film) since the active layer 4 including Al may be prevented from being exposed to the atmosphere during the manufacturing process. Thus, it is advantageous in that generation of defect can be prevented in a semiconductor laser comprising the active layer 4 including Al, and increase of leakage current and the resulting decrease of light output can be suppressed (degradation of laser characteristics can be prevented), thereby assuring the reliability of the device. In addition, yield rate can also be enhanced.

In addition, it is advantageous in that the height of the mesa structure 30B can be increased by forming the mesa structure 30B via etching, and the parasitic capacitance of the device can be reduced by employing the SI-BH structure, resulting in an enhanced high-speed response characteristic.

Additionally, it is also advantageous that the process of removing the oxide film formed in the active layer region of the mesa structure 30B need not be performed as a pre-process of the burying process, since the active layer 4 including Al is prevented from being exposed to the atmosphere and oxidized during the manufacturing process.

Here, although a case has been described wherein the light guiding layer is provided at the upper side and the lower side of the active layer 4 respectively in the manufacturing method the present embodiment, the light guiding layer may be provided either at the upper side of the active layer 4 or at the lower side of the active layer 4.

For example, if the semiconductor substrate is an n-type semiconductor substrate (a semiconductor substrate of the first conductivity type), as with the present embodiment, the process of forming the upper light guiding layer 19 may be omitted. In this case, it is preferable to arrange the cap layer 17 so as to function as the upper light guiding layer.

In addition, a p-type semiconductor substrate (p-type InP substrate: semiconductor substrate of the second conductivity type) may be used, for example, as the semiconductor substrate in the semiconductor laser, in which case the process of forming the lower light guiding layer 18 may be omitted. In this case, it is preferable to arrange the buffer layer 16 so as to function as the lower light guiding layer. In other words, when using the p-type InP substrate, it may be provided at least at the top face (n side) of the active layer 4.

In addition, the arrangement of the present embodiment may be combined with that of the second embodiment.

[Miscellaneous]

Note that, in each of the above-mentioned embodiments, although a buried layer (Fe—InP layer) composed of a semi-insulating semiconductor material (high-resistance material) is used as the buried layer composing the current blocking structure, it is by no means limiting. The buried layer composing the current blocking structure may be configured as being composed of any one type of materials chosen from a high-resistance material group including semi-insulating semiconductor material, or polyimide.

In addition, in each of the above mentioned embodiments, although the first protective layer 6A and the second protective layer 6B are made to function as the Fe—InP layer, with the same material or composition as with the first buried layer 9A and the second buried layer 9B, it is by no means limiting. The first protective layer 6A and the second protective layer 6B need not be of the same material or composition as the first buried layer 9A and the second buried layer 9B, and it suffices that they are formed using at least an aluminum-free semi-insulating semiconductor material (high-resistance material).

Furthermore, in each of the above-mentioned embodiments, although a Fabry-Perot semiconductor laser which does not have a diffraction grating layer is described as an example, it is by no means limiting. For example, the present invention can also be applied to a Distributed Feed-Back laser or a Distributed Bragg Reflector laser having a diffraction grating layer. The present invention can also be applied to, for example, a semiconductor modulator (such as an electric field absorption type modulator: EA modulator) having a similar structure with the semiconductor laser of each of the above-mentioned embodiments, and other semiconductor devices such as a semiconductor laser or a semiconductor optical amplifier with a semiconductor modulator integrated. Here, in the case of a modulator, the active layer composed of a semiconductor material including aluminum is an absorption layer (current injection layer or voltage applied layer). Application of the present invention to a modulator of a similar arrangement as with the semiconductor laser according to each of the above-mentioned embodiments results in an enhanced high-speed modulation characteristic while assuring reliability of the device.

Furthermore, in each of the above-mentioned embodiments, although a semiconductor laser formed on an n-type InP substrate (semiconductor substrate of the first conductivity type) is described as an example, it is by no means limiting. For example, the laser may be formed on a p-type InP substrate (semiconductor substrate of the second conductivity type), or on a substrate composed of a semiconductor material other than InP (GaAs substrate, for example) Additionally, in each of the above-mentioned embodiments, although a semiconductor laser configured by forming, on the InP substrate, a multi quantum well active layer 4 composed of InAlGaAs material systems mixed crystal is described as an example, semiconductor devices having an active layer composed of a semiconductor material including aluminum Al are by no means limited to this one. The present invention can also be applied to a semiconductor device having an active layer, composed of an AlGaAs related semiconductor material, formed on the GaAs substrate. Furthermore, the active layer need not be a quantum well structure, but may be a bulk structure or may be a quantum dot structure.

Note that the present invention, which is by no means intended to be limited to each of the above-mentioned embodiments, can be modified in various ways within a range that does not deviate from the concept of the present invention.

What is claimed is:

1. A semiconductor device comprising:
a mesa structure formed on a semiconductor substrate and including a first cladding layer, an active layer and a second cladding layer; a first protective layer and a second protective layer each covering respective side of said active layer; a cap layer formed between said first protective layer and said second protective layer and covering the top surface of said active layer and including aluminum only in said active layer;
a buried layer burying said mesa structure; wherein said first cladding layer, said first protective layer, said second protective layer, and said second cladding layer constitute the side of said mesa structure.

2. The semiconductor device according to claim 1, wherein said mesa structure has a buffer layer under said active layer, and said cap layer and said buffer layer are configured to function as a light guiding layer.

3. The semiconductor device according to claim 1, wherein said mesa structure has a light guiding layer composed of an aluminum-free semiconductor material at the upper side or at the lower side of said active layer, said first protective layer and said second protective layer, and the band-gap energy of said light guiding layer is lower than the band-gap energy of said first protective layer and said second protective layer.

4. The semiconductor device according to claim 1, wherein said first protective layer and said second protective layer are configured to have a refractive index smaller than that of said active layer.

5. The semiconductor device according to claim 1, wherein said buried layer comprises any one of the materials selected from a group of high-resistance materials including semi-insulating semiconductor materials and polyimide.

6. The semiconductor device according to claim 1, wherein said first protective layer and said second protective layer comprise a semi-insulating semiconductor material.

7. The semiconductor device according to claim 1, wherein said first protective layer, said second protective layer, and said buried layer are composed of the same material and composition.

8. The semiconductor device according to claim 1, wherein said first protective layer and said second protective layer have a portion composed of one material or composition, and a portion composed of another material or composition.

9. The semiconductor device according to claim 1, wherein said semiconductor substrate is an InP substrate, and said active layer composed of InAlGaAs material systems.

10. A manufacturing method of a semiconductor device comprising:
forming, on a semiconductor substrate, a first cladding layer composed of an aluminum-free semiconductor material and a protective layer composed of an aluminum-free semiconductor material;
forming a groove in said protective layer;
forming, within said groove, an active layer composed of a semiconductor material including aluminum;
forming a cap layer composed of an aluminum-free semiconductor material such that said cap layer covers the top surface of said active layer;
forming, over said protective layer and said cap layer, a second cladding layer composed of an aluminum-free semiconductor material;
forming a mesa structure including said first cladding layer, said active layer, said cap layer, said protective layer, and said second cladding layer such that said mesa structure has a width larger than the width of said active layer.

11. The manufacturing method of a semiconductor device according to claim 10 further comprising:
forming, as said cap layer, a cap layer which can serve as an upper light guiding layer; and
forming, within said groove, a buffer layer which can serve as a lower light guiding layer, before forming said active layer.

12. The manufacturing method of a semiconductor device according to claim 10 further comprising:
forming, after having formed said cap layer and before forming said second cladding layer, an upper light guiding layer composed of an aluminum-free semiconductor material; and
forming, after having formed said first cladding layer and before forming said protective layer, a lower light guiding layer composed of an aluminum-free semiconductor material.

13. The manufacturing method of a semiconductor device according to claim 10 further comprising:
forming, after having formed said first cladding layer and before forming said protective layer, a lower light guiding layer composed of an aluminum-free semiconductor material, if said semiconductor substrate is an n-type semiconductor substrate.

14. The manufacturing method of a semiconductor device according to claim 10 further comprising:
forming, after having formed said cap layer and before forming said second cladding layer, an upper light guiding layer composed of an aluminum-free semiconductor material, if said semiconductor substrate is a p-type semiconductor substrate.

15. The manufacturing method of a semiconductor device according to claim 10 further comprising:
forming, on said first cladding layer, said protective layer by forming a layer composed of one material or composition and further forming a layer composed of another material or composition.
